(19) United States
(12) Patent Application Publication
(10) Pub. No.: US 2023/0337390 A1
(43) Pub. Date: Oct. 19, 2023

(54) AIR MOVER HEALTH CHECK

(71) Applicant: Cisco Technology, Inc., (US)

(72) Inventors: Phong Hoang Ho, Cary, NC (US); Niels-Peder M. Jensen, Sunnyvale, CA (US); Stephen Aubrey Scearce, Apex, NC (US); Robert Vincent Grimes, Apex, NC (US); Lauren Ashleigh Buck, Fuquay-Varina, NC (US)

(73) Assignee: Cisco Technology, Inc., San Jose, CA (US)

(21) Appl. No.: 17/720,055

(22) Filed: Apr. 13, 2022

(51) Int. Cl. H05K 7/20; G06F 1/20; G01H 1/00; G05D 23/01

(52) U.S. Cl. CPC H05K 7/20172; G06F 1/203; G01H 1/003; G05D 23/015

(57) ABSTRACT

An air mover may be provided. The air mover may comprise an air mover motor shaft, a bearing, a bearing housing, a circuit board, an accelerometer device, a temperature sensing device, and a controller. The air mover motor shaft may be associated with a motor. The bearing housing may support the bearing that supports rotation of the air mover motor shaft. The circuit board may be attached to the bearing housing. The accelerometer device may be disposed on the circuit board. The temperature sensing device may be disposed on the circuit board wherein the temperature sensing device may be located on the circuit board in order to obtain a temperature of the bearing housing. The controller may be disposed on the circuit board and may be operative to control the motor, collect vibration data from the accelerometer device, and collect temperature data from the temperature sensing device.

### TECHNICAL FIELD

The present disclosure relates generally to health checks for air movers.

### BACKGROUND

There are a variety of rack mount enclosures currently available that draw external air and pass the air through and out of the enclosure. As the moving air passes by operating circuits within the enclosure, the air carries away heat from the operating circuits thus maintaining the operating circuits within a normal operating temperature range for proper operation and reliability.

One conventional rack mount enclosure is 1 U (approximately 1.75 inches) in height and includes a fan assembly configured as a field replaceable unit (FRU). The fan assembly includes a fan frame and a row of four fans fastened to the fan frame. The fan frame includes a vertical face plate which faces outwardly from the front of the enclosure and two thumbscrews secured to the vertical face plate. The vertical face plate and the thumbscrews are offset from the profiles of the four fans in order to avoid obstructing the airflow generated by the fans. The thumbscrews thread into thumbscrew holes defined by the enclosure thus holding the frame to the enclosure to prevent the fan assembly from inadvertently escaping (e.g., due to vibration).

### BRIEF DESCRIPTION OF THE FIGURES

The accompanying drawings, which are incorporated in and constitute a part of this disclosure, illustrate various embodiments of the present disclosure. In the drawings:

FIG. 1 illustrates a device comprising a plurality of air movers;

FIG. 2A illustrates an air mover;

FIGS. 2B and 2C illustrate a circuit board associated with an air mover;

FIG. 3 is a flow chart of a method for providing air mover health checks;

FIG. 4 is a block diagram of a computing device.

### DETAILED DESCRIPTION

### Overview

An air mover may be provided. The air mover may comprise an air mover motor shaft, a bearing, a bearing housing, a circuit board, an accelerometer device, a temperature sensing device, and a controller. The air mover motor shaft may be associated with a motor. The bearing housing may support the bearing that supports rotation of the air mover motor shaft. The circuit board may be attached to the bearing housing. The accelerometer device may be disposed on the circuit board. The temperature sensing device may be disposed on the circuit board wherein the temperature sensing device may be located on the circuit board in order to obtain a temperature of the bearing housing. The controller may be disposed on the circuit board and may be operative to control the motor, collect vibration data from the accelerometer device, and collect temperature data from the temperature sensing device.

Both the foregoing overview and the following example embodiments are examples and explanatory only and should not be considered to restrict the disclosure's scope, as described, and claimed. Furthermore, features and/or variations may be provided in addition to those described. For example, embodiments of the disclosure may be directed to various feature combinations and sub-combinations described in the example embodiments.

### EXAMPLE EMBODIMENTS

The following detailed description refers to the accompanying drawings. Wherever possible, the same reference numbers are used in the drawings and the following description to refer to the same or similar elements. While embodiments of the disclosure may be described, modifications, adaptations, and other implementations are possible. For example, substitutions, additions, or modifications may be made to the elements illustrated in the drawings, and the methods described herein may be modified by substituting, reordering, or adding stages to the disclosed methods. Accordingly, the following detailed description does not limit the disclosure. Instead, the proper scope of the disclosure is defined by the appended claims.

Air movers' health and reliability may depend on many things, including but not limited to, the air mover's fan's bearing temperature, bearing service life, and rotational balance. Accordingly, there may be a need for checking, measuring, and tracking relevant air moving parameters in, for example, a router or a switching system to provide a measure of air mover health. Having an accurate and up to date measure of the air mover's fan health may lead to a reduction in abrupt fan failures and subsequent system downtime. In addition, prediction of upcoming fan failure or degradation may allow users to select an optimum maintenance window for corrective action.

Embodiments of the disclosure may incorporate inexpensive electronic sensors into a system's air movers that may allow the air movers to be monitored for key system health indicators. Embodiments of the disclosure may detect and predict upcoming mechanical failure modes with the intention of alerting users proactively to an imminent failure or the end of the air mover's service life. This alert system may be integrated into the system telemetry in a network access controller to provide real time feedback of the cooling system health and upcoming maintenance requirements.

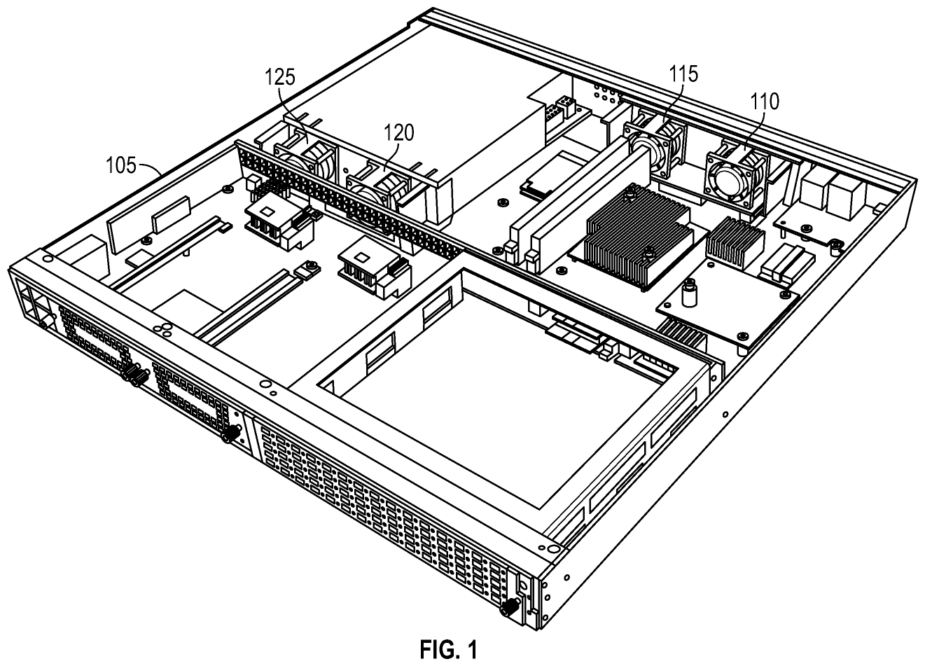

FIG. 1 illustrates a device 105 comprising a plurality of air movers. The plurality of air movers may comprise a first air mover 110, a second air mover 115, a third air mover 120, and a fourth air mover 125. Each of the plurality of air movers may be of a similar construction. The plurality of air movers may be used to cool components in device 105. Device 105 may comprise, but is not limited to, a router or a switch for example.

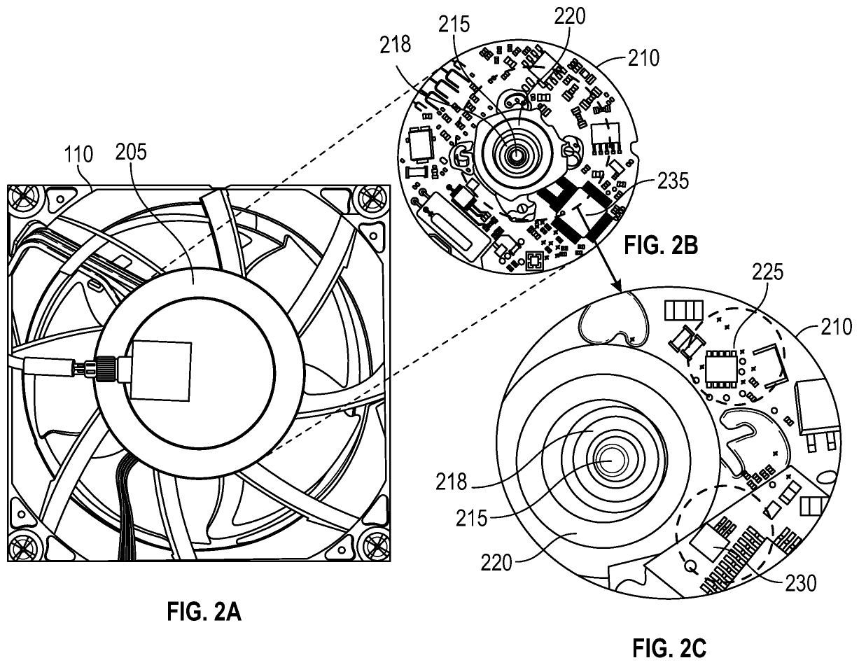

FIG. 2A illustrates first air mover 110 having a circuit board housing 205. While first air mover 110 is discussed, the same description may apply to second air mover 115, third air mover 120, and fourth air mover 125 as well. FIGS. 2B and 2C illustrate first air mover 110 with circuit board housing open in order to reveal a circuit board 210, an air mover motor shaft 215, a bearing 218, and a bearing housing 220. An electric motor associated with first air mover 110 may be disposed on the opposite side of circuit board 210. Bearing housing 220 may support bearing 218 that may support the rotation of air mover motor shaft 215 that may extend from the electric motor. Circuit board 210 may be attached to bearing housing 220.

An accelerometer device 225 may be disposed on circuit board 210. In addition, a temperature sensing device 230 may be disposed on circuit board 210. Because accelerometer device 225 is on circuit board 210 that is attached to bearing housing 220, accelerometer device 225 may obtain the acceleration time response in the X, Y, and Z directions of air mover 110. As shown in FIG. 2C, temperature sensing device 230 may be located on circuit board 210 in order to obtain a temperature of bearing housing 220. In other words temperature sensing device 230 may be place on circuit board 210 as close as possible to or even touching bearing housing 220. Furthermore, a controller 235 may be disposed on circuit board 210. The controller may be operative to control the electric motor, collect vibration data from accelerometer device 225, and collect temperature data from temperature sensing device 230.

Embodiments of the disclosure may provide inexpensive electronic sensors (e.g., accelerometer device 225 and temperature sensing device 230) on circuit board 210 that may allow first air mover 110 to be monitored for key system health indicators. The aforementioned inexpensive electronic sensors, for example, may comprise, but are not limited to, Micro-Electromechanical Systems (MEMS). MEMS may comprise small integrated devices or systems that combine mechanical and electrical components. They may be fabricated using Integrated Circuit (IC) batch processing techniques and may range in size from a few micrometers to millimeters.

Accelerometer device 225 may capture motion in all three coordinate axes and may be mounted on circuit board 210 in first air mover 110. This sensor (accelerometer device 225) may be used to capture time based data of fan vibration. The data may be used to determine, but is not limited to, the following: i) fan balance; ii) bearing 218 failure (e.g., in bearing housing 220); iii) external system vibration; iv) broken fan mounts; v) beat vibration; vi) seismic events; vii) excessive chassis vibration; and viii) dust accumulation. Vibration may be used to directly predict bearing health of bearing 218 in bearing housing 220.

Temperature sensing device 230 may capture bearing housing 220's temperature. This sensor (e.g., temperature sensing device 230) may be located on circuit board 210 in air mover 110 next to bearing housing 220. The temperature of bearing housing 220 may be directly used to predict bearing health of bearing 218 in bearing housing 220 and whether bearing 218 in bearing housing 220 is near the end of its service life.

Embodiments of the disclosure my further include controller 235 with increased memory. The increased memory may be used to store, but is not limited to, the following: i) fan revolutions per minute (RPM) parameters; ii) fan RPM values; iii) output from temperature sensing device 230; iv) service start date; v) current service hours; vi) fan current; vii) bearing temperature; viii) output data from accelerometer device 225; and ix) output from additional devices (e.g., MEMs devices). Controller 235 may track these parameters over time and compare them to target values to indicate when first air mover 110 is approaching its end of life. In other words, controller 235 may detect and predict upcoming mechanical failure modes and may alert users proactively to an imminent failure or the end of the air mover's service life.

Consistent with embodiments of the disclosure, additional data that may be measured and/or stored that may pertain to pressure differences, electrical changes, noise pollution, and ambient room information. Stored parameters may then be used to assess air mover health. One example may be to measure of the amount of current the fan is consuming in operation and to compare that measured value to an expected value stored for reference. This current measurement may be used to predict air mover health. Another example may be to measure the air mover's RPM at a specified speed setting and to compare that measured value to an expected value stored for reference. A further example may be to use the stored initial service date of the air mover to compare with the current operating date of the host machine. The number of hours of air mover service may comprise a direct measurement of service life. The health information may provide a user with proactive and timely data on the health of the air movers. This may alert the user to any imminent failure on the horizon or if the air mover is nearing the end of its service life.

In other embodiments, rather than controller 235 processing the aforementioned data, controller 235 may provide the data to a remote computing system that may receive the data, process it, and detect and predict upcoming mechanical failure modes and may alert users proactively to an imminent failure or the end of the air mover's service life. This remote computing system may be implemented by a network access controller (i.e., a Software-Defined Network (SDN) controller).

Regardless of whether the processing is done by controller 235 or by a remote computing system, embodiments of the disclosure may use an accelerometer sensor (e.g., accelerometer device 225) and a set of algorithms to generate spectral data in order to assess fan balance, fan mounting integrity, vibration entering the host machine (e.g., device 105) from external forces, and frequencies associated with bearing wear-out. With the incorporated sensors (e.g., accelerometer device 225 and temperature sensing device 230) embodiments of the disclosure may measure bearing temperature and monitor the temperature and vibration periodically over the life of the air mover (e.g., first air mover 110). Using bearing temperature, spectral vibration, and a set of bearing life prediction algorithms, embodiments of the disclosure may predict the health and service life of the air mover bearing 218 (e.g., in bearing housing 220).

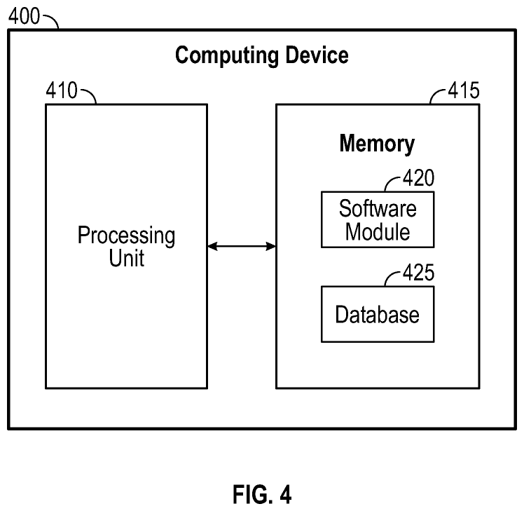

The elements described above (e.g., controller 235 and remote computing system) may be practiced in hardware and/or in software (including firmware, resident software, micro-code, etc.) or in any other circuits or systems. The elements described above may be practiced in electrical circuits comprising discrete electronic elements, packaged or integrated electronic chips containing logic gates, a circuit utilizing a microprocessor, or on a single chip containing electronic elements or microprocessors. Furthermore, the elements described above may also be practiced using other technologies capable of performing logical operations such as, for example, AND, OR, and NOT, including but not limited to, mechanical, optical, fluidic, and quantum technologies. As described in greater detail below with respect to FIG. 4, the elements described above may be practiced in a computing device 400.

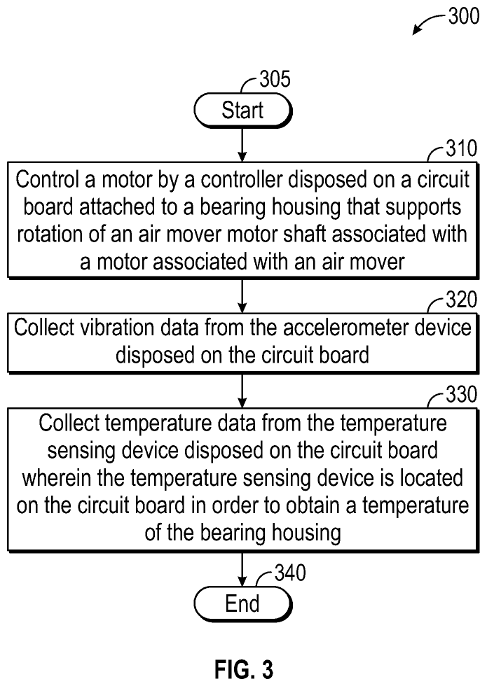

FIG. 3 is a flow chart setting forth the general stages involved in a method 300 consistent with an embodiment of the disclosure for providing air mover health checks. Method 300 may be implemented using controller 235 or a remote computing system as described in more detail above with respect to FIGS. 2A, 2B, and 2C. Ways to implement the stages of method 300 will be described in greater detail below.

Method 300 may begin at starting block 305 and proceed to stage 310 where controller 235 may control a motor associated with first air mover 110. For example, controller 235 may control first air mover 110 in such a way as to cool components in device 105.

From stage 310, where controller 235 controls the motor associated with first air mover 110, method 300 may advance to stage 320 where controller 235 may collect vibration data from accelerometer device 225 disposed on circuit board 210. For example, accelerometer device 225 may capture motion in all three coordinate axes and may be mounted on circuit board 210 in first air mover 110. Accelerometer device 225 may be used to capture time based data of fan vibration. The data may be used to determine, but is not limited to, the following: i) fan balance; ii) bearing 218 failure (e.g., in bearing housing 220); iii) external system vibration; iv) broken fan mounts; v) beat vibration; vi) seismic events; vii) excessive chassis vibration; and viii) dust accumulation. Vibration may be used to directly predict bearing health of bearing 218 in bearing housing 220. Accelerometer device 225 may provide this data to controller 235 where it may be stored, processed, or sent to a remote processing system for processing.

Once controller 235 collects vibration data from accelerometer device 225 disposed on circuit board 210 in stage 320, method 300 may continue to stage 330 where controller 235 may collect temperature data from temperature sensing device 230 disposed on circuit board 210. Temperature sensing device 230 may be located on circuit board 210 in order to obtain a temperature of bearing housing 220. For example, temperature sensing device 230 may capture bearing housing 220's temperature. Temperature sensing device 230 may be located on circuit board 210 in the air mover next to bearing housing 220. The temperature of bearing housing 220 may be directly used to predict bearing health of bearing 218 in housing 220 and whether the bearings in bearing 218 in housing 220 are near the end of their service life. Temperature sensing device 230 may provide this data to controller 235 where it may be stored, processed, or sent to a remote processing system for processing.

As stated above, controller 235 may be used to store, but is not limited to: i) fan revolutions per minute (RPM) parameters; ii) fan RPM values; iii) output from temperature sensing device 230; iv) service start date; v) current service hours; vi) fan current; vii) bearing 218 temperature; viii) output data from accelerometer device 225; and ix) output from additional devices (e.g., MEMs devices). Controller 235 may track these parameters over time and compare them to target values to indicate when first air mover 110 is approaching its end of life. In other words, controller 235 may detect and predict upcoming mechanical failure modes and may alert users proactively to an imminent failure or the end of the air mover's service life. In other embodiments, rather than controller 235 processing the data, controller 235 may provide the data to a remote computing system that may receive the data, process it, and detect and predict upcoming mechanical failure modes and may alert users proactively to an imminent failure or the end of the air mover's service life.

Regardless of whether the processing is done by controller 235 or by a remote computing system, embodiments of the disclosure may use accelerometer device 225 and a set of algorithms to generate spectral data in order to assess fan balance, fan mounting integrity, vibration entering device 105 from external forces, and frequencies associated with bearing wear-out. With accelerometer device 225 and temperature sensing device 230, embodiments of the disclosure may measure bearing temperature and monitor the temperature and vibration periodically over the life of first air mover 110. Using bearing temperature, spectral vibration, and a set of bearing life prediction algorithms, embodiments of the disclosure may predict the health and service life of the air mover bearing 218 in bearing housing 220. Once controller 235 collects the temperature data from temperature sensing device 230 disposed on circuit board 210 in stage 340, method 300 may then end at stage 340.

FIG. 4 shows computing device 400. As shown in FIG. 4, computing device 400 may include a processing unit 410 and a memory unit 415. Memory unit 415 may include a software module 420 and a database 425. While executing on processing unit 410, software module 420 may perform, for example, processes for providing air mover health checks as described above with respect to FIG. 3. Computing device 400, for example, may provide an operating environment for controller 235 or remote computing system. Controller 235 and remote computing system may operate in other environments and are not limited to computing device 400.

Computing device 400 may be implemented using a Wi-Fi access point, a tablet device, a mobile device, a smart phone, a telephone, a remote control device, a set-top box, a digital video recorder, a cable modem, a personal computer, a network computer, a mainframe, a router, a switch, a server cluster, a smart TV-like device, a network storage device, a network relay device, or other similar microcomputer-based device. Computing device 400 may comprise any computer operating environment, such as hand-held devices, multiprocessor systems, microprocessor-based or programmable sender electronic devices, minicomputers, mainframe computers, and the like. Computing device 400 may also be practiced in distributed computing environments where tasks are performed by remote processing devices. The aforementioned systems and devices are examples, and computing device 400 may comprise other systems or devices.

Embodiments of the disclosure may comprise a system. The system may comprise an air mover motor shaft associated with a motor associated with an air mover; a bearing housing that supports a bearing that supports rotation of the air mover motor shaft; a circuit board attached to the bearing housing; an accelerometer device disposed on the circuit board; a temperature sensing device disposed on the circuit board wherein the temperature sensing device is located on the circuit board in order to obtain a temperature of the bearing housing; and a controller disposed on the circuit board wherein the controller may be operative to; control the motor, collect vibration data from the accelerometer device, and collect temperature data from the temperature sensing device. The controller may be further operative to use the vibration data to predict health of the air mover. The controller may be further operative to use the temperature data to predict health of the air mover. The controller may be further operative to provide the vibration data to a computing device remote from the air mover that predicts health of the air mover. The controller may be further operative to provide the temperature data to a computing device remote from the air mover that predicts health of the air mover. The accelerometer device may comprise a Micro-Electromechanical System (MEMS). The temperature sensing device comprises a Micro-Electromechanical System (MEMS).

Embodiments of the disclosure may comprise a method. The method may comprise controlling a motor by a controller disposed on a circuit board attached to a bearing housing that supports a bearing that supports rotation of an air mover motor shaft associated with a motor associated with an air mover; collecting vibration data from the accelerometer device disposed on the circuit board; and collecting temperature data from the temperature sensing device disposed on the circuit board wherein the temperature sensing device is located on the circuit board in order to obtain a temperature of the bearing housing. The method may further comprise using, by the controller, the vibration data to predict health of the air mover. The method may further comprise using, by the controller, the temperature data to predict health of the air mover. The method may further comprise providing, by the controller, the vibration data to a computing device remote from the air mover that predicts health of the air mover. The method may further comprise providing, by the controller, the temperature data to a computing device remote from the air mover that predicts health of the air mover. The accelerometer device may comprise a Micro-Electromechanical System (MEMS). Temperature sensing device may comprise a Micro-Electromechanical System (MEMS).

Embodiments of the disclosure may comprise a computer-readable medium that stores a set of instructions which when executed perform a method executed by the set of instructions comprising: controlling a motor by a controller disposed on a circuit board attached to a bearing housing that supports a bearing that supports rotation of an air mover motor shaft associated with a motor associated with an air mover; collecting vibration data from the accelerometer device disposed on the circuit board; and collecting temperature data from the temperature sensing device disposed on the circuit board wherein the temperature sensing device is located on the circuit board in order to obtain a temperature of the bearing housing. The set of instructions may further comprise using, by the controller, the vibration data to predict health of the air mover. The set of instructions may further comprise using, by the controller, the temperature data to predict health of the air mover. The set of instructions may further comprise providing, by the controller, the vibration data to a computing device remote from the air mover that predicts health of the air mover. The set of instructions may further comprise providing, by the controller, the temperature data to a computing device remote from the air mover that predicts health of the air mover. The accelerometer device may comprise a first Micro-Electromechanical System (MEMS) and the temperature sensing device may comprise a second MEMS.

Embodiments of the disclosure, for example, may be implemented as a computer process (method), a computing system, or as an article of manufacture, such as a computer program product or computer readable media. The computer program product may be a computer storage media readable by a computer system and encoding a computer program of instructions for executing a computer process. The computer program product may also be a propagated signal on a carrier readable by a computing system and encoding a computer program of instructions for executing a computer process. Accordingly, the present disclosure may be embodied in hardware and/or in software (including firmware, resident software, micro-code, etc.). In other words, embodiments of the present disclosure may take the form of a computer program product on a computer-usable or computer-readable storage medium having computer-usable or computer-readable program code embodied in the medium for use by or in connection with an instruction execution system. A computer-usable or computer-readable medium may be any medium that can contain, store, communicate, propagate, or transport the program for use by or in connection with the instruction execution system, apparatus, or device.

The computer-usable or computer-readable medium may be, for example but not limited to, an electronic, magnetic, optical, electromagnetic, infrared, or semiconductor system, apparatus, device, or propagation medium. More specific computer-readable medium examples (a non-exhaustive list), the computer-readable medium may include the following: an electrical connection having one or more wires, a portable computer diskette, a random access memory (RAM), a read-only memory (ROM), an erasable programmable read-only memory (EPROM or Flash memory), an optical fiber, and a portable compact disc read-only memory (CD-ROM). Note that the computer-usable or computer-readable medium could even be paper or another suitable medium upon which the program is printed, as the program can be electronically captured, via, for instance, optical scanning of the paper or other medium, then compiled, interpreted, or otherwise processed in a suitable manner, if necessary, and then stored in a computer memory.

While certain embodiments of the disclosure have been described, other embodiments may exist. Furthermore, although embodiments of the present disclosure have been described as being associated with data stored in memory and other storage mediums, data can also be stored on, or read from other types of computer-readable media, such as secondary storage devices, like hard disks, floppy disks, or a CD-ROM, a carrier wave from the Internet, or other forms of RAM or ROM. Further, the disclosed methods' stages may be modified in any manner, including by reordering stages and/or inserting or deleting stages, without departing from the disclosure.

Furthermore, embodiments of the disclosure may be practiced in an electrical circuit comprising discrete electronic elements, packaged or integrated electronic chips containing logic gates, a circuit utilizing a microprocessor, or on a single chip containing electronic elements or microprocessors. Embodiments of the disclosure may also be practiced using other technologies capable of performing logical operations such as, for example, AND, OR, and NOT, including but not limited to, mechanical, optical, fluidic, and quantum technologies. In addition, embodiments of the disclosure may be practiced within a general purpose computer or in any other circuits or systems.

Embodiments of the disclosure may be practiced via a system-on-a-chip (SOC) where each or many of the element illustrated in FIG. 2 may be integrated onto a single integrated circuit. Such an SOC device may include one or more processing units, graphics units, communications units, system virtualization units and various application functionality all of which may be integrated (or “burned”) onto the chip substrate as a single integrated circuit. When operating via an SOC, the functionality described herein with respect to embodiments of the disclosure, may be performed via application-specific logic integrated with other components of computing device 400 on the single integrated circuit (chip).

Embodiments of the present disclosure, for example, are described above with reference to block diagrams and/or operational illustrations of methods, systems, and computer program products according to embodiments of the disclosure. The functions/acts noted in the blocks may occur out of the order as shown in any flowchart. For example, two blocks shown in succession may in fact be executed substantially concurrently or the blocks may sometimes be executed in the reverse order, depending upon the functionality/acts involved.

While the specification includes examples, the disclosure's scope is indicated by the following claims. Furthermore, while the specification has been described in language specific to structural features and/or methodological acts, the claims are not limited to the features or acts described above. Rather, the specific features and acts described above are disclosed as example for embodiments of the disclosure.

1. A system comprising:
an air mover motor shaft associated with a motor associated with an air mover;
a bearing that supports rotation of the air mover motor shaft wherein the bearing is in a bearing housing;
a circuit board attached to the bearing housing;
an accelerometer device disposed on the circuit board;
a temperature sensing device disposed on the circuit board wherein the temperature sensing device is located on the circuit board in order to obtain a temperature of the bearing housing; and
a controller disposed on the circuit board wherein the controller is operative to:
control the motor,
collect vibration data from the accelerometer device, and
collect temperature data from the temperature sensing device.

2. The system of claim 1, wherein the controller is further operative to use the vibration data to predict health of the air mover.

3. The system of claim 1, wherein the controller is further operative to use the temperature data to predict health of the air mover.

4. The system of claim 1, wherein the controller is further operative to provide the vibration data to a computing device remote from the air mover that predicts health of the air mover.

5. The system of claim 1, wherein the controller is further operative to provide the temperature data to a computing device remote from the air mover that predicts health of the air mover.

6. The system of claim 1, wherein the accelerometer device comprises a Micro-Electromechanical System (MEMS).

7. The system of claim 1, wherein the temperature sensing device comprises a Micro-Electromechanical System (MEMS).

8. The system of claim 1, wherein the controller is further operative to:
collect additional data from the air mover, the additional data comprising at least one of the following: motor revolutions per minute (RPM) parameters, motor RPM values, air mover service start date, current air mover service hours, and motor current; and
use the additional data to predict health of the air mover.

9. A method comprising:
controlling a motor by a controller disposed on a circuit board attached to a bearing housing that supports a bearing that supports rotation of an air mover motor shaft associated with a motor associated with an air mover;
collecting vibration data from an accelerometer device disposed on the circuit board; and
collecting temperature data from a temperature sensing device disposed on the circuit board wherein the temperature sensing device is located on the circuit board in order to obtain a temperature of the bearing housing.

10. The method of claim 9, further comprising using, by the controller, the vibration data to predict health of the air mover.

11. The method of claim 9, further comprising using, by the controller, the temperature data to predict health of the air mover.

12. The method of claim 9, further comprising providing, by the controller, the vibration data to a computing device remote from the air mover that predicts health of the air mover.

13. The method of claim 9, further comprising providing, by the controller, the temperature data to a computing device remote from the air mover that predicts health of the air mover.

14. The method of claim 9, wherein the accelerometer device comprises a Micro-Electromechanical System (MEMS) and wherein the temperature sensing device comprises a Micro-Electromechanical System (MEMS).

15. A computer-readable medium that stores a set of instructions which when executed perform a method executed by the set of instructions comprising:
controlling a motor by a controller disposed on a circuit board attached to a bearing housing that supports a bearing that supports rotation of an air mover motor shaft associated with a motor associated with an air mover;
collecting vibration data from an accelerometer device disposed on the circuit board; and
collecting temperature data from a temperature sensing device disposed on the circuit board wherein the temperature sensing device is located on the circuit board in order to obtain a temperature of the bearing housing.

16. The computer-readable medium of claim 15, further comprising using, by the controller, the vibration data to predict health of the air mover.

17. The computer-readable medium of claim 15, further comprising using, by the controller, the temperature data to predict health of the air mover.

18. The computer-readable medium of claim 15, further comprising providing, by the controller, the vibration data to a computing device remote from the air mover that predicts health of the air mover.

19. The computer-readable medium of claim 15, further comprising providing, by the controller, the temperature data to a computing device remote from the air mover that predicts health of the air mover.

20. The computer-readable medium of claim 15, wherein the accelerometer device comprises a first Micro-Electromechanical System (MEMS) and wherein the temperature sensing device comprises a second MEMS.
